(19) United States
(12) Patent Application Publication
(10) Pub. No.: US 2025/0267820 A1
(43) Pub. Date: Aug. 21, 2025

(54) DEVICE WITH INTEGRATED LIQUID COOLING SYSTEM

(71) Applicant: Mellanox Technologies Ltd., Yokneam (IL)

(72) Inventors: Oren WELTSCH, Golan Heights (IL); Rom BECKER, Ramat Yishai (IL); Shay ZARETSKY, Qiryat Mozkin (IL); Ayal SHABTAY, Haifa (IL); Beeri HALACHMI, Kohav Yair (IL); Yuval BLAYER, Avtalyon (IL); Kfir KATZ, Tivon (IL); Yuval DAGAN, Gilon (IL); Bar NOYMAN, Kfar Hachoresh (IL)

(73) Assignee: Mellanox Technologies Ltd., Yokneam (IL)

(21) Appl. No.: 19/184,039

(22) Filed: Apr. 21, 2025

Related U.S. Application Data
(63) Continuation-in-part of application No. 17/534,645, filed on Nov. 24, 2021, now Pat. No. 12,284,783.

(51) Int. Cl. H05K 7/20

(52) U.S. Cl. CPC H05K 7/20263; H05K 7/20154; H05K 7/20272

(57) ABSTRACT

A device may include: a frame having an interior; an electronic component; a heat conducting body in thermal contact with the electronic component; a conduit containing a liquid coolant, the conduit being coupled to the heat conducting body to deliver the liquid coolant to and from the heat conducting body; and a pump positioned within the interior of the frame, the pump being removably insertable into the interior of the frame and being removably couplable to the conduit to circulate the liquid coolant through the conduit.

### CROSS-REFERENCE TO RELATED APPLICATIONS

This application is a continuation-in-part of U.S. patent application Ser. No. 17/534,645 filed Nov. 24, 2021, which is hereby incorporated by reference in its entirety.

### BACKGROUND

Typically, network devices in network systems, such as for example network switch devices, include heat producing electronic components that may require cooling. Cooling of heat producing electronic components may be done using air and/or liquid. Air cooling of heat producing electronic components is typically less effective than liquid cooling thereof. For example, air cooling systems typically have smaller maximal power and smaller power density as compared to liquid cooling systems. Liquid cooling of heat producing electronic components typically requires dedicated infrastructure at the network system facility to distribute cooling liquid between network system devices and to cool the cooling liquid. The infrastructure may, for example, include pumps, valves, controllers, cooling towers and other components known in the art. Some network system facilities have no such dedicated infrastructure to support liquid cooling of heat producing electronic components of the network devices.

### GENERAL DESCRIPTION

Some embodiments may provide a device or other component including: a frame having an interior; an electronic component; a heat conducting body in thermal contact with the electronic component; a conduit containing a liquid coolant, the conduit being coupled to the heat conducting body to deliver the liquid coolant to and from the heat conducting body; and a pump positioned within the interior of the frame, the pump being removably insertable into the interior of the frame and being removably couplable to the conduit to circulate the liquid coolant through the conduit.

In some embodiments, the device may include a heat sink positioned within the interior of the frame, wherein at least a portion of the conduit passes through the heat sink.

In some embodiments, the heat sink may include a plurality of fins that are parallel to an axis extending between a first end and a second end of the frame.

In some embodiments, the device may include one or more fan receptacles at a first end of the frame, each of the fan receptacles being configured to removably receive a fan.

In some embodiments, the pump is removably insertable into the interior of the frame through one of the fan receptacles.

In some embodiments, the device may include one or more fans each being removably received within one of the fan receptacles.

In some embodiments, the device may include a coupler having a first dripless blind-mate connector and a second dripless blind-mate connector to removably couple the pump to the conduit.

In some embodiments, the device may include a second pump positioned within the interior of the frame, the second pump being coupled to the conduit to circulate the liquid coolant through the conduit.

In some embodiments, the device may include a coupler to couple in parallel the pump and the second pump to the conduit.

In some embodiments, the coupler may include: a first dripless blind-mate connector and a second dripless blind-mate connector to removably couple the pump to the conduit, and a third dripless blind-mate connector and a fourth dripless blind-mate connector to removably couple the second pump to the conduit.

In some embodiments, the device may include a controller to control the pump and the second pump to maintain a desired flow rate of the liquid coolant through the conduit.

In some embodiments, the controller is a central processing unit (CPU) of the device.

In some embodiments, the device is a network switch device.

Some embodiments may provide a device including: a housing having: a first end, a second end, and an interior; a heat producing component or device; a cooling body in thermal contact with the heat producing component; a conduit containing a coolant, the conduit being coupled to the cooling body to deliver the coolant to and from the cooling body; a heat exchanger positioned within the interior of the housing and having at least a portion of the conduit passing therethrough; one or more fan openings at the first end of the housing; one or more fans each being removably received within one of the fan openings; and a first pump and a second pump positioned within the interior of the housing, the first pump and the second pump being removably insertable into the interior of the housing through one of the fan openings and being removably couplable in parallel to the conduit to circulate the coolant through the conduit.

In some embodiments, the device may include a coupler including: a first dripless blind-mate connector and a second dripless blind-mate connector to removably couple the first pump to the conduit, and a third dripless blind-mate connector and a fourth dripless blind-mate connector to removably couple the second pump to the conduit.

In some embodiments, the heat exchanger may include a heat sink.

In some embodiments, the heat sink may include a plurality of fins that are parallel to an axis extending between the first end and the second end of the housing.

In some embodiments, the device may include a controller to control the first pump and the second pump to maintain a desired flow rate of the coolant through the conduit.

In some embodiments, the controller controlling the one or more fans to maintain a desired flow rate of air into the interior of the housing.

In some embodiments, the controller is a central processing unit (CPU) of the device.

In some embodiments, the device is a network switch device.

Some embodiments may provide a device including: a frame; a heat producing device; a cooling body in contact with the heat producing device; a coolant conduit delivering coolant to the cooling body; and a pump positioned within the frame, to circulate the liquid coolant in the conduit.

In some embodiments, the device is a network switch device.

Some embodiments may provide a device, which may include: a frame including: a first end, a second end, a bottom surface, a first side wall and a second side wall extending between the first end and the second end, and an interior; a first pump drawer and a second pump drawer positioned within the interior of the frame, the first pump drawer positioned above the second pump drawer, relative to the bottom surface of the frame and along the first side wall of the frame; and a first pump positioned within the first pump drawer and a second pump positioned within the second pump drawer, the first pump and the second pump being removably coupled to a conduit using a plurality of dripless blind-mate connectors; wherein each of the first pump drawer with the first pump and the second pump drawer with the second pump is replaceable without terminating the operation of the device.

In some embodiments, the device may include a plurality of fans positioned at the first end of the frame between the first side wall and the second side wall, the fans to introduce an airflow into the interior of the frame, wherein the first pump drawer and the second pump drawer are positioned in front of a fan of the plurality of fans.

In some embodiments, each of the first pump drawer and the second pump drawer tapers towards the first side wall of the frame in a direction towards the first end of the frame including the fans.

In some embodiments, a fan of the plurality of fans that is positioned adjacent to the first side wall is removably received within a fan receptacle, the fan being replaceable without terminating the operation of the device, and wherein each of the first pump drawer with the first pump and the second pump drawer with the second pump is replaceable through the fan receptacle.

In some embodiments, a width of the first pump drawer and the second pump drawer is smaller than a width of a fan of the plurality of fans that is positioned adjacent to the first side wall of the frame.

In some embodiments, the first pump drawer and the second pump drawer partly interfere with the airflow into the interior of the frame provided by a fan of the plurality of fans that is positioned adjacent to the first side wall of the frame.

In some embodiments, the first pump and the second pump operate simultaneously.

In some embodiments, the first pump operates, and the second pump a is activated if a rotational speed of the first pump reduces below a predefined threshold.

In some embodiments, the device may include a controller to control the first pump and the second pump to maintain a desired flow rate of the liquid coolant through the conduit.

In some embodiments, the controller is a central processing unit of the device.

In some embodiments, the device may include a heat sink positioned within the interior of the frame, wherein a portion of the conduit passes through the heat sink, the heat sink to cause heat to dissipate from the liquid coolant through the portion of the conduit passing through the heat sink to cool the liquid coolant.

In some embodiments, the device may include: an electronic component positioned in the interior of the frame, and a cooling body in thermal contact with the electronic component, the cooling body being coupled to the conduit to deliver a liquid coolant to and from the cooling body.

Some embodiments may provide a device, which may include: a frame including an interior; a cooling body positioned in the interior of the frame; a conduit containing a liquid coolant, the conduit being coupled to the cooling body; and a pump removably coupled to the conduit using a plurality of dripless connectors, the pump being positioned within the interior of the frame along a side wall of the frame, the pump being replaceable without terminating the operation of the device.

In some embodiments, the device may include a plurality of fans positioned at one end of the frame.

In some embodiments, a fan of the plurality of fans that is positioned adjacent to the side wall of the frame is removably received within a fan receptacle, the fan being replaceable without terminating the operation of the device.

In some embodiments, the pump is replaceable through the fan receptacle.

In some embodiments, a width of the pump is smaller than a width of a fan of the plurality of fans that is positioned adjacent to the side wall of the frame.

In some embodiments, the pump partly interferes with an airflow into the interior of the frame provided by a fan of the plurality of fans that is positioned adjacent to the side wall of the frame.

In some embodiments, the pump is supported within a pump drawer, the pump drawer extending along the side wall of the frame.

In some embodiments, the pump drawer tapers towards the side wall of the frame in a direction towards an end of the frame including a plurality of fans.

### BRIEF DESCRIPTION OF THE DRAWINGS

Various embodiments in accordance with the present disclosure will be described with reference to the drawings, in which:

FIG. 1 is a three-dimensional (3D) diagram of a network switch device, in accordance with certain embodiments;

FIG. 2 is a 3D diagram of an enlarged portion of a heat exchanger or heat sink of a network switch device, in accordance with certain embodiments;

FIG. 3 is a 3D diagram of the network switch device showing transparent view of pump sub-frames, in accordance with certain embodiments;

FIG. 4 is a 3D diagram of a section view, along line A-A of FIG. 1, of a network switch device, in accordance with certain embodiments;

FIGS. 5A and 5B are a 3D diagram and a top view, respectively, of a network switch device, in accordance with certain embodiments;

FIGS. 6A and 6B are a 3D diagram and a top view, respectively, of a frame, a pump sub-frame and fans of a network switch device, in accordance with certain embodiments; and

FIGS. 7A and 7B are 3D diagrams of a pump sub-frame supporting a pump, in accordance with certain embodiments.

It will be appreciated that, for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following description, various aspects of the present disclosure are described. For purposes of explanation, specific configurations and details are set forth in order to provide a thorough understanding of the present disclosure. However, it will also be apparent to one skilled in the art that the present disclosure can be practiced without the specific details presented herein. Furthermore, well known features can have been omitted or simplified in order not to obscure the present disclosure. With specific reference to the drawings, it is stressed that the particulars shown are by way of example and for purposes of illustrative discussion of the present disclosure only and are presented in the cause of providing what is believed to be the most useful and readily understood description of the principles and conceptual aspects of the disclosure. In this regard, no attempt is made to show structural details of the disclosure in more detail than is necessary for a fundamental understanding of the disclosure, the description taken with the drawings making apparent to those skilled in the art how the several forms of the disclosure can be embodied in practice.

Before at least one embodiment of the disclosure is explained in detail, it is to be understood that the disclosure is not limited in its application to the details of construction and the arrangement of the components set forth in the following description or illustrated in the drawings. The disclosure is applicable to other embodiments that can be practiced or carried out in various ways as well as to combinations of the disclosed embodiments. Also, it is to be understood that the phraseology and terminology employed herein is for the purpose of description and should not be regarded as limiting.

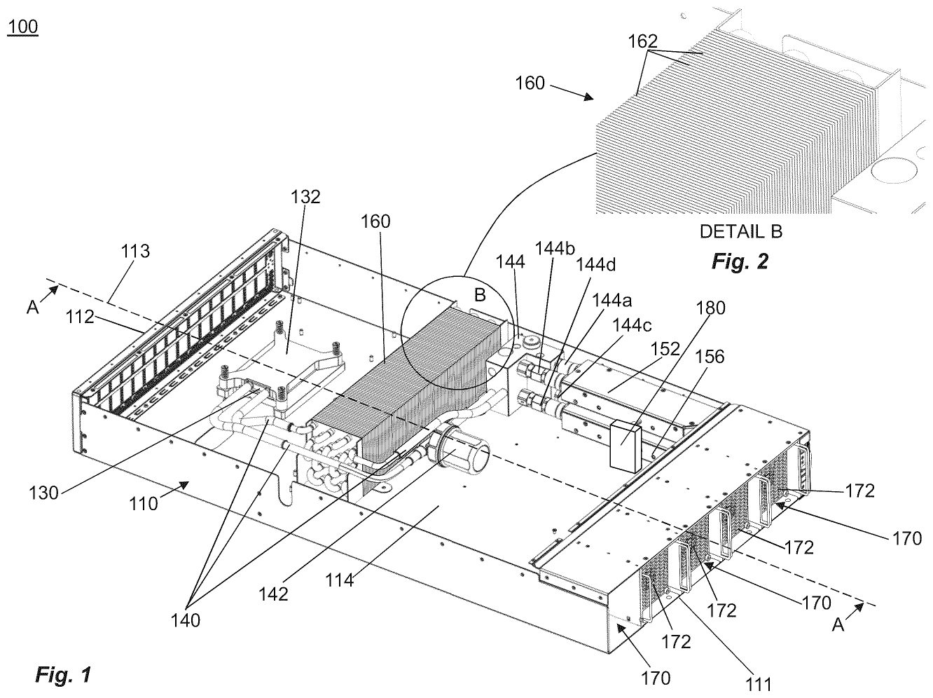

Reference is now made to FIG. 1, which is a three-dimensional (3D) diagram of a network switch device 100, in accordance with certain embodiments.

Reference is also made to FIG. 2, which is a 3D diagram of an enlarged portion of a heat exchanger or heat sink 160 of network switch device 100, in accordance with certain embodiments.

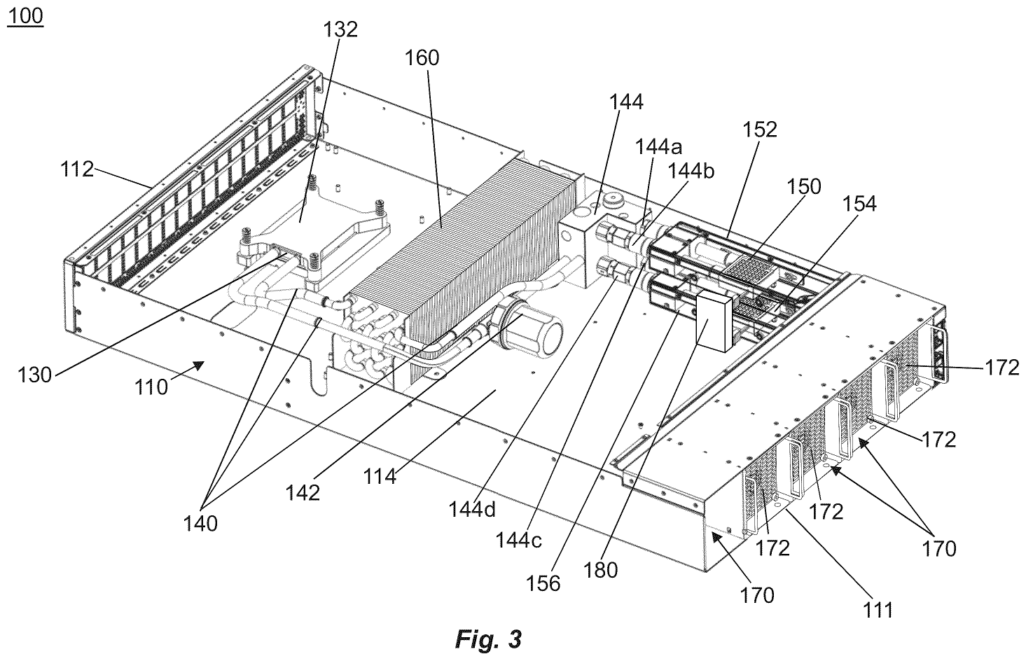

Reference is also made to FIG. 3, which is a 3D diagram of network switch device 100 showing transparent view of pump sub-frames 152, 156, in accordance with certain embodiments.

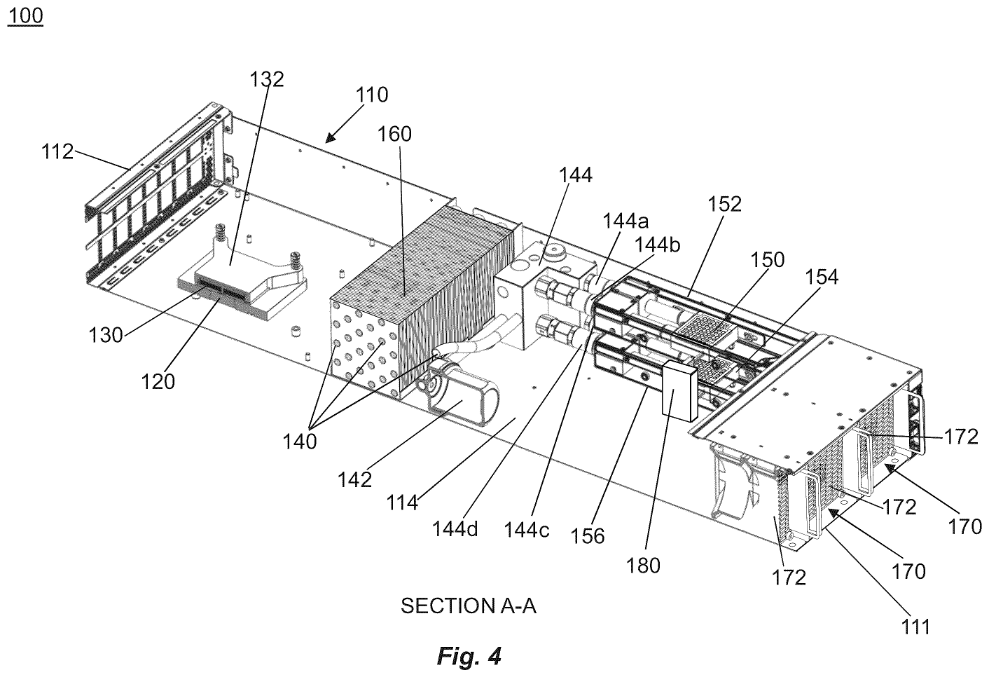

Reference is also made to FIG. 4, which is a 3D diagram of a section view, along line A-A of FIG. 1, of network switch device 100, in accordance with certain embodiments.

According to some embodiments, network switch device 100 may include a frame or housing 110, an electronic component or device or heat producing component 120, a heat conducting or cooling body 130, a conduit 140 and a pump 150. While device 100 is described as a network switch device, other devices may include components as described herein.

Frame or housing 110 may have a first end 111, a second end 112 and an interior 114. Electronic component 120 may be positioned within interior 114 of frame or housing 110. Electronic component 120 may produce heat. For example, electronic component 120 may be a central processing unit (CPU), graphics processing unit (GPU), networking application-specific integrated circuit (ASIC) or any other heat producing electronic component of network switch device 100.

Heat conducting or cooling body 130 may be in thermal contact with electronic component 120. Heat conducting or cooling body 130 may be made of or may include material such as, for example, copper, aluminum or stainless steel. For example, heat conducting or cooling body 130 may contact, directly or indirectly, electronic component 120 to cause heat to dissipate from electronic component 120 to heat conducting or cooling body 130. In some embodiments, network switch device 100 may include a heat conducting or cooling body sub-frame 132 to couple heat conducting or cooling body 130 to frame or housing 110 and/or to secure the position of heat conducting or cooling body 130 with respect to electronic component 120.

Conduit 140, e.g., a pipe, tube, possibly in one or more connected sections, may contain a coolant, for example, a liquid coolant. The coolant may, for example, be or include water (e.g., pure water) or water solutions (e.g., glycol-water). Conduit 140 may be coupled to or be in contact with heat conducting or cooling body 130. Conduit 140 may deliver the coolant to and from heat conducting or cooling body 130. In some embodiments, conduit 140 includes two or more interconnected conduit portions. In some embodiments, network switch device 100 may include an expansion tank 142 coupled to or in contact with conduit 140.

Pump 150 may be positioned within interior 114 of frame or housing 110. For example, pump 150 may be positioned adjacent (or substantially adjacent) to first end 111 of frame or housing 110. Pump 150 may be positioned along (e.g. adjacent (or substantially adjacent) to) a side wall of frame or housing 110. Pump 150 may be coupled to conduit 140 to circulate the coolant through conduit 140 and to deliver the coolant to and from heat conducting or cooling body 130. Pump 150 may be a centrifugal pump. Pump 150 may be, for example, direct current pump having controllable rotational speed and rotational speed feedback circuity.

Network switch device 100 may include a heat exchanger or heat sink 160. Heat exchanger or heat sink 160 may be positioned within interior 114 of frame or housing 110. In some embodiments, heat exchanger or heat sink 160 may include a plurality of fins 162. Fins 162 may be parallel (or substantially parallel) to an axis 113 extending between first end 111 and second end 112 of frame or housing 110. At least a portion of conduit 140 may pass through heat exchanger or heat sink 160. For example, the portion of conduit 140 passing through heat exchanger or heat sink 160 may be curved such that two or more turns of conduit 140 pass through heat exchanger or heat sink 160.

Network switch device 100 may include one or more fan receptacles or openings 170 at first end 111 of frame or housing 110. Each of fan receptacles or openings 170 may removably receive a fan. Network switch device 100 may include one or more fans 172 each being removably received within one of fan receptacles or openings 170.

In some embodiments, pump 150 may be removably inserted into interior 114 of frame or housing 110 through one of fan receptacles or openings 170. In some embodiments, network switch device 100 may include a coupler 144 to removably couple pump 150 to conduit 140. Coupler 144 may, for example, include a first dripless blind-mate connector 144a and a second dripless blind-mate connector 144b to removably couple pump 150 to conduit 140. In some embodiments, pump 150 may be positioned within a pump sub-frame or drawer 152. Pump-sub-frame 152 may be removably coupled (e.g., using bolts or any suitable locking mechanism capable of releasably securing pump sub-frame 152) to frame or housing 110. Pump sub-frame 152 may have dimensions that are smaller than dimensions of fan receptacles or openings 170 to removably insert pump sub-frame 152 into interior 114 of frame or housing 110 through one of fan receptacles or openings 170. Pump sub-frame 152 may ensure proper position of pump 150 with respect to conduit 140 and/or coupler 144. Pump 150 and/or pump sub-frame 152 may only partly interfere with an airflow into interior 114 of frame or housing 110 provided by fan 172 that is positioned next to the side wall of frame or housing 110. Pump 150 and/or pump sub-frame 152 may not interfere (or substantially not interfere) with airflow an airflow into interior 114 of frame or housing 110 provided by fans 172 other than fan 172 that is positioned next to the side wall of frame or housing 110.

Pump 150 and/or fans 172 may be hot swap units. Hot swapping may refer to replacement or addition of components to a computer system without stopping, shutting down, or rebooting the system. Pump 150 and/or fans 172 may be replaced (e.g., plugged in and/or unplugged) without terminating the operation of network switch device 100, e.g., without stopping, shutting down, or rebooting network switch device 100. Pump 150, pump sub-frame 152 and/or fans 172 may be field replaceable unit (FRUs). Pump 150, pump sub-frame 152 and/or fans 172 may be replaced (e.g., plugged in and/or unplugged) by a technician or end user without specialized tools or extensive disassembly of network switch device 100.

In operation, electronic component 120 of network switch device 100 may produce heat. Pump 150 may circulate the coolant through conduit 140 to deliver the coolant to and from heat conducting or cooling body 130 being in thermal contact with electronic component 120. Heat being produced by electronic component 120 may dissipate from electronic component 120 through heat conducting or cooling body 130 to the coolant to cool the electronic component 120. Fans 172 may draw air into interior 114 of frame or housing 110. The air may flow through heat exchanger or heat sink 160 to cause heat to dissipate from the coolant through the portion of conduit 140 passing through heat exchanger or heat sink 160 to the air to cool the coolant.

In various embodiments, network switch device 100 may include a controller 180 to control pump 150 and/or fans 172. In various embodiments, the CPU of network switch device 100 may control pump 150 and/or fans 172.

Controller 180 and/or the CPU of network switch device 100 may control rotational speed of pump 150 to generate and maintain a desired flow rate of the coolant through conduit 140. In some embodiments, pump 150 may include a rotational speed feedback circuity. The rotational speed feedback circuity may output a signal indicative of the actual rotational speed of pump 150. Controller 180 and/or the CPU of network switch device 100 may receive the signal and send signals to pump 150 to control pump 150 based on the signal from the rotational speed feedback circuity of the respective pump. In some embodiments, network switch device 100 may include a flow rate sensor to measure the flow rate of the coolant through conduit 140 and to generate an output signal related thereto. Controller 180 and/or the CPU of network switch device 100 may control pump 150 further based on the output signal from the flow rate sensor. In various embodiments, controller 180 and/or the CPU of network switch device 100 may issue a notification if the rotational speed of pump 150 or decreases below a predefined threshold.

Controller 180 and/or the CPU of network switch device 100 may control rotational speed of fans 172 based on a temperature of one or more components of network switch device 100. For example, electronic component 120 may include a temperature sensor to measure a temperature of electronic component 120 and generate an output signal related thereto. Controller 180 and/or the CPU of network switch device 100 may, for example, detect that the temperature of electronic component 120 increases above a predefined threshold (e.g., based on the output signal from the temperature sensor of electronic component 120) and control fans 172 to increase their respective rotational speed to increase the flow rate of air through heat exchanger or heat sink 160. Increased flow rate of air through heat exchanger or heat sink 160 may enhance the cooling of the coolant flowing through conduit 140, which in turn may enhance the cooling of electronic component 120. In some embodiments, network switch device 100 may include a coolant temperature sensor to measure the temperature of the coolant in conduit 140 and generate an output signal related thereto. Controller 180 and/or the CPU of network switch device 100 may control the rotational speed of fans 172 further based on the output signal from the coolant temperature sensor to maintain the desired temperature of the coolant.

In some embodiments, each of fans 172 may include a rotational speed feedback circuity. The rotational speed feedback circuity may output a signal indicative of the actual rotational speed of the respective fan. Controller 180 and/or the CPU of network switch device 100 may receive the signal and output a signal to control fans 172 based on the signals from rotational speed feedback control circuities of fans 172. For example, if controller 180 and/or the CPU of network switch device 100 detects that the rotational speed of one of fans 172 has smaller value than a preset value thereof, controller 180 and/or the CPU of network switch device 100 may control other fans 172 to increase their respective rotational speeds to maintain the desired flow rate the air through heat exchanger or heat sink 160. In some embodiments, controller 180 and/or the CPU of network switch device 100 may issue a notification if the rotational speed of one of fans 172 decreases below a predefined threshold.

In operation, if the rotational speed of pump 150 falls below the predefined threshold, pump 150 may be replaced with new pump without terminating the operation of network switch device 100. For example, one of fans 172 may be removed from its respective fan receptacle or opening and pump 150 may be decoupled from coupler 144, pulled external to frame or housing 110 through the respective fan receptacle or opening, and new pump such as pump 150 may be inserted into frame or housing 110 and coupled to coupler 144. The replacement operations may be performed without terminating the operation of network switch device 100 since pump 150 and fans 172 may be hop swap and/or field replacement units.

In some embodiments, network switch device 100 may include a second pump 154. Pump 154 may be provided for redundancy, for example in case of pump failure. Pump 154 may be, for example, direct current pump having controllable rotational speed and rotational speed feedback circuity. Pump 154 may be a centrifugal pump. Pump 154 may be positioned within interior 114 of frame or housing 110. For example, pump 154 may be positioned adjacent (or substantially adjacent) to first end 111 of frame or housing 110. Pump 154 may be positioned along (e.g. adjacent (or substantially adjacent) to) the side wall of frame or hosing 110. Pump 150 may be positioned above pump 150 relative to a bottom surface of frame or housing 110. Pump 154 may be removably inserted into interior 114 of frame or housing 110 through one of fan receptacles or openings 170, for example through the same fan receptacle or opening 170 being used to insert and remove pump 150 into/from interior 114 of frame or housing 110. In some embodiments, coupler 144 may include a third dripless blind-mate connector 144c and a fourth dripless blind-mate connector 144d to removably couple pump 154 to conduit 140. For example, coupler 144 may couple in parallel pump 150 and pump 154 to conduit 140. In some embodiments, pump 154 may be positioned within a second pump sub-frame or drawer 156. Pump sub-frame 156 may be removably coupled (e.g., using bolts or any suitable locking mechanism capable of releasably securing pump sub-frame 152) to frame or housing 110. Pump sub-frame 156 may have dimensions that are smaller than dimensions of fan receptacles or openings 170 to removably insert pump sub-frame 156 into interior 114 of frame or housing 110 through one of fan receptacles or openings 170. Pump sub-frame 156 may ensure proper position of pump 154 with respect to conduit 140 and/or coupler 144. Although two pumps 150, 154 are shown in FIGS. 1-4, it is to be understood that in various embodiments, network switch device 100 may include a single pump or more than two pumps.

Pumps 150, 154 and/or pump sub-frames 152, 156 may only partly interfere with an airflow into interior 114 of frame or housing 110 provided by fan 172 that is positioned next to the side wall of frame or housing 110. Pumps 150, 154 and/or pump sub-frames 152, 156 may not interfere (or substantially not interfere) with airflow an airflow into interior 114 of frame or housing 110 provided by fans 172 other than fan 172 that is positioned next to the side wall of frame or housing 110.

Pump 154 may be a hot swap unit. Pump 154 may be replaced (e.g., plugged in and/or unplugged) without terminating the operation of network switch device 100, e.g., without stopping, shutting down, or rebooting network switch device 100. Pump 154 and pump sub-frame 156 may be field replaceable unit (FRU). Pump 154 and pump sub-frame 156 may be replaced (e.g., plugged in and/or unplugged) by a technician or end user without specialized tools or extensive disassembly of network switch device 100.

Controller 180 and/or the CPU of network switch device 100 may control rotational speeds of pump 150 and/or pump 154 to generate and maintain the desired flow rate of the coolant through conduit 140. Controller 180 and/or the CPU of network switch device 100 may control pump 150 and pump 154 based on, for example, output signals from rotational speed feedback circuities of pump 150 and pump 154 and/or based on the output signal from the flow rate sensor (e.g., as described hereinabove).

In one example, both pump 150 and pump 154 may operate simultaneously during normal operation of network switch device 100. If controller 180 and/or the CPU of network switch device 100 detects that the rotational speed of one of pump 150 or pump 154 has smaller value than a preset value thereof, controller 180 and/or the CPU of network switch device 100 may control another pump of pump 150 or pump 154 to increase its respective rotational speed to maintain the desired flow rate of the coolant through conduit 140.

In another example, only one of pumps 150, 154 may operate during normal operation of network switch device 100, while the other pump of pumps 150, 154 may be turned off. For example, pump 150 may operate and pump 154 may be turned off during normal operation of network switch device 100. If controller 180 and/or the CPU of network switch device 100 detects that the rotational speed of pump 150 has smaller value than the preset value thereof, controller 180 and/or the CPU of network switch device 100 may turn on pump 154 and control the rotational speed of pump 154 to compensate for the reduced rotational speed of pump 150 to maintain the desired flow rate of the coolant through conduit 140. In another example, if controller 180 and/or the CPU of network switch device 100 detects that the rotational speed of pump 150 has smaller value than the preset value thereof, controller 180 and/or the CPU of network switch device 100 may turn off pump 150 and turn on pump 154 and control the rotational speed of pump 154 to provide the desired flow rate of the coolant through conduit 140.

In various embodiments, controller 180 and/or the CPU of network switch device 100 may issue a notification if the rotational speed of one of pump 150 and/or pump 154 decreases below a predefined threshold. The rotational speed which is below the predefined threshold may be indicative of, for example, a malfunction of the respective pump.

In operation, if the rotational speed of one of pump 150 or pump 154 reduces below the predefined threshold, the respective pump (e.g., referred herein below as “faulty pump”) may be replaced with new pump without terminating the operation of network switch device 100. For example, one of fans 172 may be removed from its respective fan receptacle or opening and the faulty pump may be decoupled from coupler 144 and pulled external to frame or housing 110 through the respective fan receptacle or opening. Once one of fans 172 is removed, controller 180 and/or the CPU of network switch device 100 may increase rotational speeds of remaining fans 172 to maintain the desired flow rate of air through heat exchanger or heat sink 160. Once the faulty pump is decoupled from conduit 140/coupler 144, dripless blind-mate connectors to which the faulty pump was coupled may prevent the coolant from leaking external to conduit 140. Once the faulty pump is decoupled from conduit 140/coupler 144, controller 180 and/or the CPU of network switch device 100 may increase the rotational speed of the remaining pump to maintain the desired flow rate of the coolant through conduit 140. New pump may be inserted into interior 114 of frame or housing 110 through the respective fan receptacle or opening and coupled to conduit 140/coupler 144 by the respective dripless blind-mate connectors. The fan that has been removed may be inserted back to the respective fan receptacle or opening. Controller 180 and/or the CPU of network switch device 100 may control the pumps and the fans in a normal mode of operation, e.g., as described hereinabove.

Components of network switch device 100 such as cooling body 130, conduit 140, pump 150 and/or pump 154 may provide or form a closed-loop liquid cooling subsystem. Hot swap pump 150 and/or hot swap pump 154 may circulate the liquid coolant through the closed-loop cooling subsystem without loss of the liquid coolant during the operation, while heat sink 160 may dissipate the heat from a portion of conduit 140 passing through heat sink 160 to air introduced into interior 114 of frame or housing 110 by fans 172.

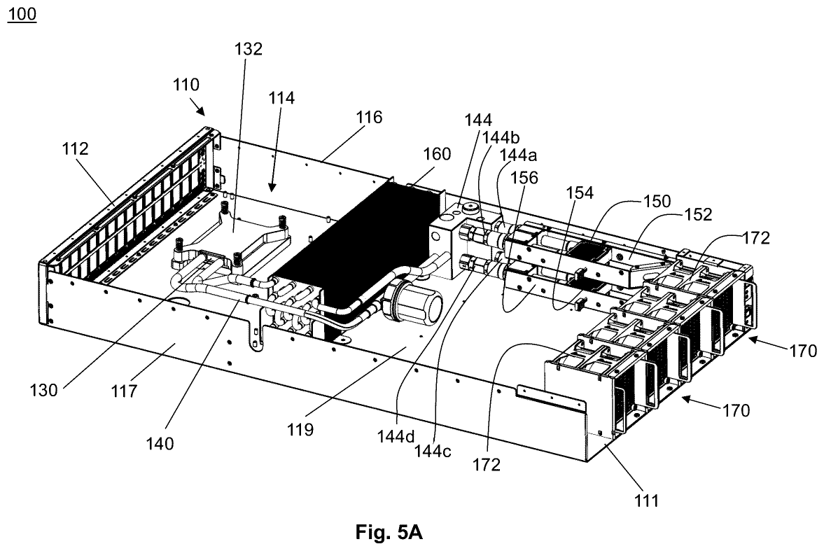

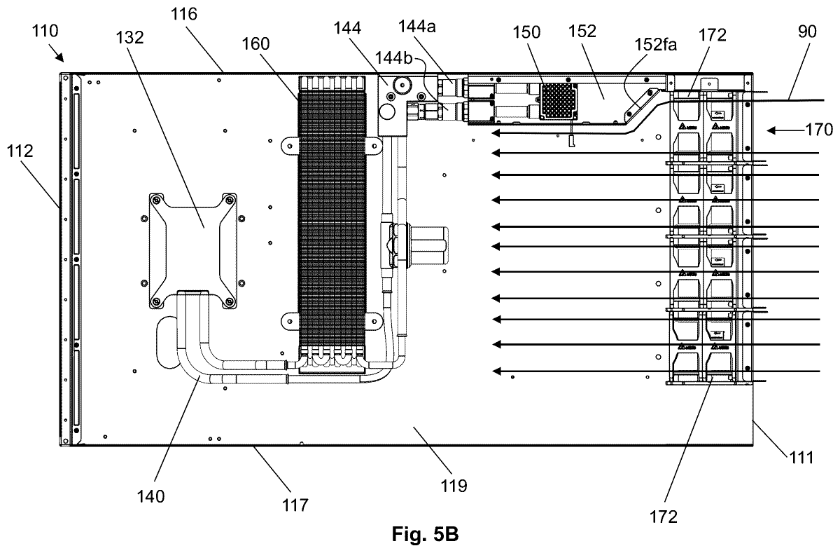

Reference is made to FIGS. 5A and 5B, which are a 3D diagram and a top view, respectively, of network switch device 100, according to some embodiments.

Frame 110 of network switch device 100 may include a first side wall 116 and a second side wall 117. First side wall 116 and second side wall 117 may be opposite to each other. Side walls 116, 117 may extend between first end 111 and second end 112 of frame 110. Frame 110 may include a bottom surface 119. Frame 110 may include a top surface or cover (not shown in FIGS. 5A and 5B for simplicity) to cover interior 114 of frame 110.

Pump sub-frame or drawer 152 supporting pump 150 may be positioned along first side wall 116 of frame 110. Pump sub-frame or drawer 156 supporting pump 154 may be positioned along first side wall 116 of frame 110. Pump sub-frame 152 may be positioned above pump sub-frame 156 relative to bottom surface 119 of frame 110. Pump sub-frames 152 and 156 may be positioned adjacent to first end 111 of frame 110 which includes fans 172. Pump sub-frames 152 and 156 may be positioned in front of fan 172 that is adjacent to first side wall 116 of frame 110. Top covers of pump sub-frames 152 and 156 are not shown in FIGS. 5A and 5B for simplicity. Positioning pump sub-frame 152 above pump sub-frame 154 relative to bottom surface 119 and along first side wall 116 of frame 110 may minimize the interference of pump sub-frames 152, 156 with an airflow 90 into interior 114 of frame 110 provided by fans 172 of network switch device 100. At most, pump sub-frames 152, 156 may only partly interfere with the airflow 90 provided by fan 172 positioned next to first side wall 116 of frame 110 (e.g. as shown in FIG. 5B). Pump sub-frames 152, 156 may not interfere (or substantially not interfere) with airflow 90 provided by fans 172 other than fan 172 positioned next to first wall 116 of frame 110. Each of pump sub-frames 152, 156 may narrow or taper towards first side wall 116 of frame 110 in a direction towards first end 111 of frame 111 (e.g. as shown in FIG. 5B). Tapered portions of pump sub-frames 152, 156 (e.g. such as tapered portion 252fa described hereinbelow) may guide airflow 90 provided by fan 172 positioned next to first side wall 116 smoothly into interior 114 of frame 110 (e.g. as shown in FIG. 5B).

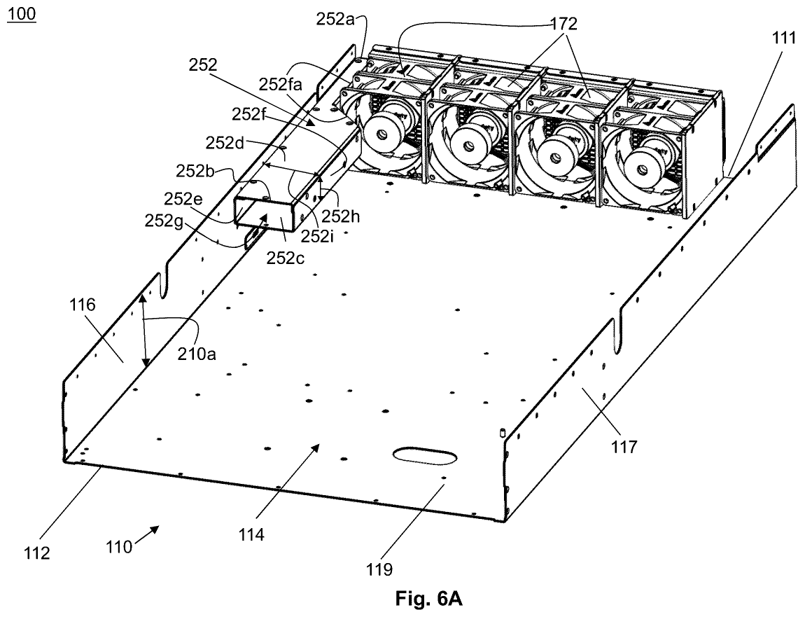

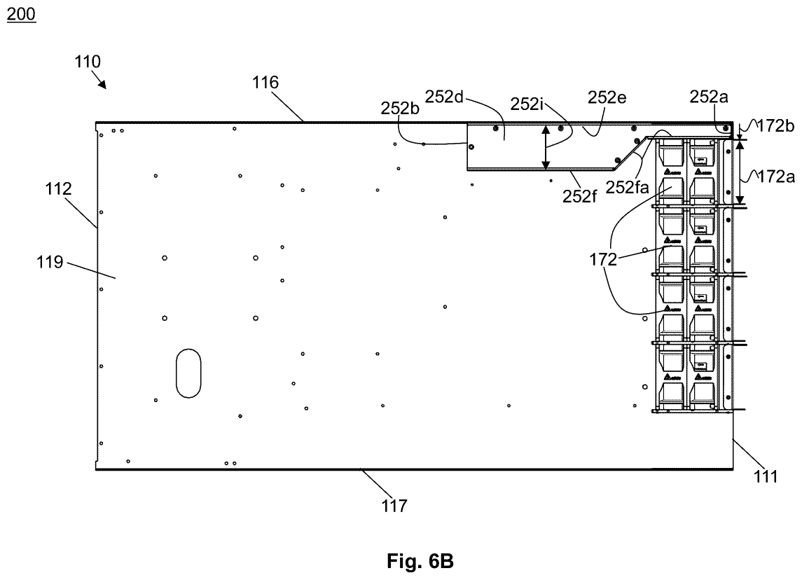

Reference is made to FIGS. 6A and 6B, which are a 3D diagram and a top view, respectively, of frame 110, a pump sub-frame or drawer 252 and fans 172 of a network switch device 100, according to some embodiments.

For simplicity and clarity of illustrations, FIGS. 6A and 6B show only frame 110, pump sub-frame 252 (e.g. such as pump sub-frames 152, 156 described hereinabove) and fans 172 of network switch device 100. While one pump sub-frame 252 is shown, in some embodiments, network switch device 100 may include more than one pump sub-frame 252, for example two pump sub-frames such as pump sub-frames 152, 156 described hereinabove.

Pump sub-frame or drawer 252 may include a first end 252a, a second end 252b, a bottom surface 252c, a top surface or cover 252d, a first side wall 252e, a second side wall 252f and an interior 252g. When positioned within an interior 114 of frame 110, first side wall 252e of pump sub-frame 252 may face or contact first side wall 116 of frame 110. Second side wall 252f of pump sub-frame 252 may include a tapered portion 252fa that tapers towards first side wall 252e of pump sub-frame 252 in a direction towards first end 252a of pump sub-frame 252.

Pump sub-frame 252 may be flat (or substantially flat). A ratio of a height 252h (measured as a distance between bottom and top surfaces 252c, 252d) to a width 252i (measured as a distance between first and second side walls 252e, 252f) of pump sub-frame 252 may range from 0.4 to 0.5; other ranges may be used. In one example, pump sub-frame 252 may have height 252h of 28 mm and width 252i of 57.6 mm, providing height 252h to width 252i ratio of 0.486; other dimensions may be used.

A ratio of height 252h of pump sub-frame 252 to a height 110a (measured as a distance between bottom surface 119 and the top surface or cover) of frame 110 may range from 0.3 to 0.4; other ranges may be used. In one example, pump sub-frame 252 may have height 252h of 28 mm and frame 111 may have height 110a of 88.1 mm, providing height 252h to height 110a ratio of 0.317. Accordingly, frame 110 of network switch device 200 may accommodate at least two pump sub-frames 252 (e.g. pump subframes 152, 156 as described hereinabove) positioned one above the other relative to bottom surface 119 of frame 110 (e.g. as described hereinabove).

Width 252i of pump sub-frame 252 may be smaller than a width 272i of fan 272 (or fan opening 270). A ratio of width 252i of pump sub-frame 252 to width 272i of fan 272 (or fan opening 270) may range from 0.65 to 0.75; other ranges may be used. In one example, pump sub-frame 252 may have width 252i of 57.6 mm and fan 272 may have width 272a of 80 mm, providing width 252i to width 272a ratio of 0.72; other values may be used. Fans 272 may be offset from first side wall 116 toward second side wall 117 of frame 110 (e.g. as indicated by arrow 272b in FIG. 6B). Offsetting fans 272 from first side wall 215 of frame 110 may reduce the interference of pump sub-frame 252 with the airflow into interior 114 of frame 110 provided by fan 272 positioned next to first side wall 116 of frame 110. In one example, fans 272 may be offset from first side wall 116 by 21.6 mm, ensuring that only 42.7 mm of pump sub-frame 252 partly interfere with fan 272 positioned next to first side wall 116 of frame 110 (which is only 0.53 of width 272a of fan 272 or fan opening 270). Tapered portion 252fa of pump sub-frame 252 may reduce the interference of pump sub-frame 252 with the airflow into interior of frame 110 provided by fan 172 positioned next to first side wall 116 of frame 110, for example by guiding the airflow smoothly into interior 114 of frame 110 (e.g. as described hereinabove). Other values and ranges may be used.

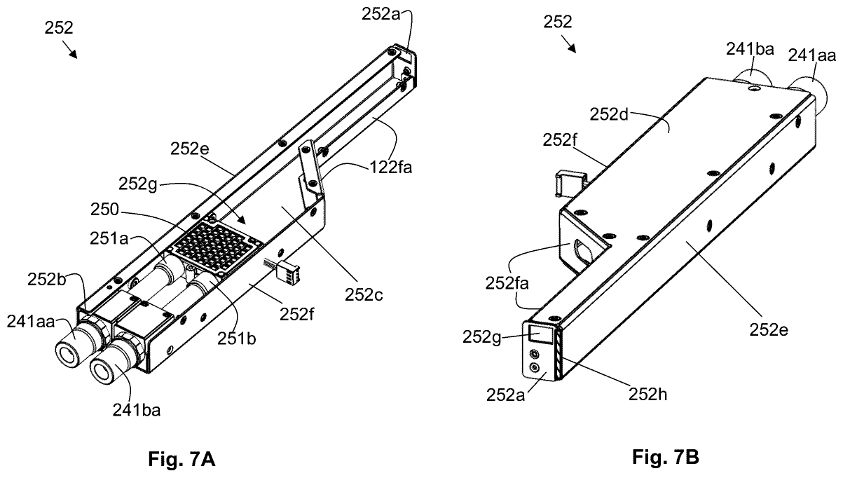

Reference is made to FIGS. 7A and 7B, which are 3D diagrams of pump sub-frame 252 supporting a pump 250, according to some embodiments. For simplicity and clarity of illustrations, top surface 252d of pump sub-frame 252 is not shown in FIG. 7A.

Pump sub-frame or drawer 252 may support pump 250 (e.g. such as pump 150, 154 described hereinabove). Pump 250 may be positioned within interior 252g of pump sub-frame 252. Pump 250 may be secured within interior 252g of pump sub-frame 252 using fasteners (e.g. bolts). Pump 250 may be flat (or substantially flat). For example, a ratio of a height (measured as a distance between bottom and top surfaces) to a width (measured as a distance between side surfaces) of pump 250 may range from 0.25 to 0.35. In one example, pump 250 may have the height of 15.1 mm and the width of 46 mm, providing the height to width ratio of 0.32. Other values and ranges may be used.

Pump 250 may include an inlet port 251a through which the liquid coolant may flow into pump 250, and an outlet port 251b through which the liquid coolant may flow out of pump 250. Both inlet port 251a and outlet port 251b of pump 250 may be positioned at the same side or end of pump 250. Inlet port 251a and outlet port 251b of pump 250 may be coupled to male or female portions 244aa, 244ba (e.g. female portions in the example of FIGS. 7A and 7B) of dripless blind-mate connectors (e.g. such as dripless blind-mate connectors 144a, 144b or 144c, 144d described hereinabove. Portions 244aa, 244ba of the dripless blind-mate connectors may project externally to interior 252g from second end 252b of pump sub-assembly 252 (e.g. as shown in FIGS. 7A and 7B).

Pump sub-frame 252 may include, e.g. at its first end 252a, a visual indicator 252g (e.g. as shown in FIG. 7B). Visual indicator 252g may indicate whether or not pump 250 accommodated within pump sub-frame 2252 is faulty. Visual indicator 252g may include a light emitting element such as a light emitting diode (LED).

Pump sub-frame 252 may include, e.g. at its first end 252a or on its first side wall 252e, a locking mechanism 252h (e.g. as schematically shown in FIG. 7B). Locking mechanism 252h may releasably secure pump sub-frame 252 in a position with respect frame 110 of network switch device 200. Locking mechanism 252h, schematically shown in FIG. 7B, may include a latch or lever handle to secure engagement of pump sub-frame 252 within the frame of the network switch device, a spring-loaded locking pin or tab to automatically secure pump sub-frame 252 in place, an ejector to safely disengage and remove pump sub-frame 252 from the frame of the network switch device and/or any other component suitable for FRU. Advantageously, the disclosed network switch device 100 includes integrated liquid cooling system and does not require any external infrastructure for supporting the liquid cooling thereof. Furthermore, in some embodiments, network switch device 100 may include two pumps 150, 154 being coupled in parallel using dripless blind-mate connectors to conduit 140 delivering the coolant to and from heat conducting or cooling body 130 being in thermal contact with heat producing component 120 of network stich device 100. In the case of malfunction of one of pumps 150, 154, the faulty pump may be replaced with new pump through one of fan receptacles or openings 170 without terminating the operation of network switch device 100 (e.g., as described hereinabove). Pumps 150, 154 may be positioned along side wall 116 of frame or housing 110 of network switch device 100. Pumps 150, 154 may be positioned one above the other relative to bottom surface 119 of frame or housing 110. Pumps 150, 154 may be supported within pump sub-frames 152, 156. Positioning pumps 150, 154 and/or pump sub-frames 152, 156 one above the other relative to the bottom surface and along side wall 116 of frame or housing 110 may minimize the interference of pumps 150, 154 and/or pump sub-frames 152, 156 with the airflow into interior 114 of frame or housing 110 provided by fans 172 of network switch device 100. At most, pumps 150, 154 and/or pump sub-frames 152, 156 may only partly interfere with the airflow provided by fan 172 positioned next to side wall 116 of frame or housing 110 of network switch device 110. Pumps 150, 154 and/or pump sub-frames 152, 156 may not interfere (or substantially not interfere) with the airflow provided by fans 172 other than fan 172 positioned next to side wall 116 of frame or housing 110 of network switch device 100.

1. A device comprising:
a frame comprising: a first end, a second end, a bottom surface, a first side wall and a second side wall extending between the first end and the second end, and an interior;
a first pump drawer and a second pump drawer positioned within the interior of the frame, the first pump drawer positioned above the second pump drawer, relative to the bottom surface of the frame and along the first side wall of the frame; and
a first pump positioned within the first pump drawer and a second pump positioned within the second pump drawer, the first pump and the second pump being removably coupled to a conduit using a plurality of dripless blind-mate connectors;
wherein each of the first pump drawer with the first pump and the second pump drawer with the second pump is replaceable without terminating the operation of the device.

2. The device of claim 1, comprising a plurality of fans positioned at the first end of the frame between the first side wall and the second side wall, the fans to introduce an airflow into the interior of the frame, wherein the first pump drawer and the second pump drawer are positioned in front of a fan of the plurality of fans.

3. The device of claim 2, wherein each of the first pump drawer and the second pump drawer tapers towards the first side wall of the frame in a direction towards the first end of the frame comprising the fans.

4. The device of claim 2, wherein a fan of the plurality of fans that is positioned adjacent to the first side wall is removably received within a fan receptacle, the fan being replaceable without terminating the operation of the device, and wherein each of the first pump drawer with the first pump and the second pump drawer with the second pump is replaceable through the fan receptacle.

5. The device of claim 2, wherein a width of the first pump drawer and the second pump drawer is smaller than a width of a fan of the plurality of fans that is positioned adjacent to the first side wall of the frame.

6. The device of claim 2, wherein the first pump drawer and the second pump drawer partly interfere with the airflow into the interior of the frame provided by a fan of the plurality of fans that is positioned adjacent to the first side wall of the frame.

7. The device of claim 1, wherein the first pump and the second pump operate simultaneously.

8. The device of claim 1, wherein the first pump operates, and the second pump a is activated if a rotational speed of the first pump reduces below a predefined threshold.

9. The device of claim 1, comprising a controller to control the first pump and the second pump to maintain a desired flow rate of the liquid coolant through the conduit.

10. The device of claim 9, wherein the controller is a central processing unit of the device.

11. The device of claim 1, comprising a heat sink positioned within the interior of the frame, wherein a portion of the conduit passes through the heat sink, the heat sink to cause heat to dissipate from the liquid coolant through the portion of the conduit passing through the heat sink to cool the liquid coolant.

12. The device of claim 1, comprising:
an electronic component positioned in the interior of the frame,
a cooling body in thermal contact with the electronic component, the cooling body being coupled to the conduit to deliver a liquid coolant to and from the cooling body.

13. A device comprising:
a frame comprising an interior;
a cooling body positioned in the interior of the frame;
a conduit containing a liquid coolant, the conduit being coupled to the cooling body; and
a pump removably coupled to the conduit using a plurality of dripless connectors, the pump being positioned within the interior of the frame along a side wall of the frame, the pump being replaceable without terminating the operation of the device.

14. The device of claim 13, comprising a plurality of fans positioned at one end of the frame.

15. The device of claim 14, wherein a fan of the plurality of fans that is positioned adjacent to the side wall of the frame is removably received within a fan receptacle, the fan being replaceable without terminating the operation of the device.

16. The device of claim 15, wherein the pump is replaceable through the fan receptacle.

17. The device of claim 14, wherein a width of the pump is smaller than a width of a fan of the plurality of fans that is positioned adjacent to the side wall of the frame.

18. The device of claim 14, wherein the pump partly interferes with an airflow into the interior of the frame provided by a fan of the plurality of fans that is positioned adjacent to the side wall of the frame.

19. The device of claim 18, wherein the pump is supported within a pump drawer, the pump drawer extending along the side wall of the frame.

20. The device of claim 19, wherein the pump drawer tapers towards the side wall of the frame in a direction towards an end of the frame comprising a plurality of fans.
